(19) United States
(12) Patent Application Publication
(10) Pub. No.: US 2025/0126961 A1
(43) Pub. Date: Apr. 17, 2025

(54) LIGHT-EMITTING ELEMENT AND DISPLAY DEVICE HAVING THE LIGHT-EMITTING ELEMENT

(71) Applicant: Japan Display Inc., Tokyo (JP)

(72) Inventor: Nobuto MANAGAKI, Tokyo (JP)

(73) Assignee: Japan Display Inc., Tokyo (JP)

(21) Appl. No.: 18/910,107

(22) Filed: Oct. 9, 2024

(30) Foreign Application Priority Data
Oct. 17, 2023 (JP) 2023-178859
May 9, 2024 (JP) 2024-076414

(51) Int. Cl. H10K 50/11; H10K 50/18; H10K 101/20; H10K 101/40

(52) U.S. Cl. CPC H10K 50/11; H10K 50/181; H10K 2101/20; H10K 2101/40

(57) ABSTRACT

Disclosed is a light-emitting element including an anode, a cathode, and an electroluminescence layer between the anode and the cathode. The electroluminescence layer includes an electron-blocking layer and an emission layer. The electron-blocking layer contains an electron-blocking material. The emission layer is located over and in contact with the electron-blocking layer and contains a host material and a first emission material exhibiting thermally activated delayed fluorescence. The light-emitting element is configured so that a resistance is equal to or greater than 101.0% and equal to or less than 104.0% of a resistance in a case where the electron-blocking material is replaced with the host material. The resistance is a resistance between the anode and the cathode when a current flows at a constant current density between the anode and the cathode.

### CROSS-REFERENCE TO RELATED APPLICATIONS

This application claims the benefit of priority to Japanese Patent Application No. 2023-178859, filed on Oct. 17, 2023, and Japanese Patent Application No. 2024-076414, filed on May 9, 2024, the entire contents of which are incorporated herein by reference.

### FIELD

An embodiment of the present invention relates to a light-emitting element and a display device having the light-emitting element.

### BACKGROUND

In recent years, display devices having organic electroluminescence elements (OLEDs) have been widely used. In addition, organic electroluminescence elements exhibiting thermally activated delayed fluorescence or hyper-fluorescence (registered trademark) have attracted much attention because of their extremely high emission efficiency, and tremendous research and development are being conducted (see, for example, Japanese Patent Application Publications No. 2021-048366, 2020-013695, and 2017-222820).

### SUMMARY

An embodiment of the present invention is a light-emitting element. The light-emitting element includes an anode, a cathode, and an electroluminescence layer between the anode and the cathode. The electroluminescence layer includes an electron-blocking layer and an emission layer. The electron-blocking layer contains an electron-blocking material. The emission layer is located over and in contact with the electron-blocking layer and contains a host material and a first emission material exhibiting thermally activated delayed fluorescence. The light-emitting element is configured so that a resistance is equal to or greater than 101.0% and equal to or less than 104.0% of a resistance in a case where the electron-blocking material is replaced with the host material. The resistance is a resistance between the anode and the cathode when a current flows at a constant current density between the anode and the cathode.

An embodiment of the present invention is a display device. The display device includes a red-emissive pixel, a green-emissive pixel, and a blue-emissive pixel each including an electroluminescence element. The electroluminescence element of at least one of the red-emissive pixel, the green-emissive pixel, and the blue-emissive pixel includes a pixel electrode, an electron-blocking layer, an emission layer, and a cathode. The electron-blocking layer is located over the pixel electrode and contains an electron-blocking material. The emission layer is located over and in contact with the electron-blocking layer and contains a host material and a first emission material exhibiting thermally activated delayed fluorescence. The cathode is located over the emission layer. The electroluminescence element of the at least one of the red-emissive pixel, the green-emissive pixel, and the blue-emissive pixel is configured so that a resistance is equal to or greater than 101.0% and equal to or less than 104.0% of a resistance in a case where the electron-blocking material is replaced with the host material. The resistance is a resistance between the pixel electrode and the cathode when a current flows at a constant current density between the pixel electrode and the cathode.

### BRIEF DESCRIPTION OF DRAWINGS

FIG. 1 is a schematic cross-sectional view of a light-emitting element according to an embodiment of the present invention.

FIG. 2 is a schematic top view of a display device according to an embodiment of the present invention.

FIG. 3A is a schematic top view of a display device according to an embodiment of the present invention.

FIG. 3B is a schematic top view of a display device according to an embodiment of the present invention.

FIG. 4 is a schematic cross-sectional view of a display device according to an embodiment of the present invention.

FIG. 5 is a schematic cross-sectional view of a light-emitting element provided in a pixel of a display device according to an embodiment of the present invention.

FIG. 6 shows voltage-current density curves of the light-emitting elements of Examples and Comparable Examples 1 and 2.

FIG. 7 shows current density-normalized external quantum efficiency curves of the light-emitting elements of Examples and Comparable Examples 1 and 2.

FIG. 8 shows voltage-capacitance curves of the light-emitting elements of Examples and Comparable Examples 1 and 2.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted.

In the specification and the claims, unless specifically stated, when a state is expressed where a structure is arranged “over” another structure, such an expression includes both a case where a structure is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, the mode expressed by this expression includes a mode where the structure is not in contact with the other structure.

### First Embodiment

In the present embodiment, an electroluminescence element (hereinafter simply referred to as “light-emitting element”) 100 according to an embodiment of the present invention is explained.

### 1. Overall Structure

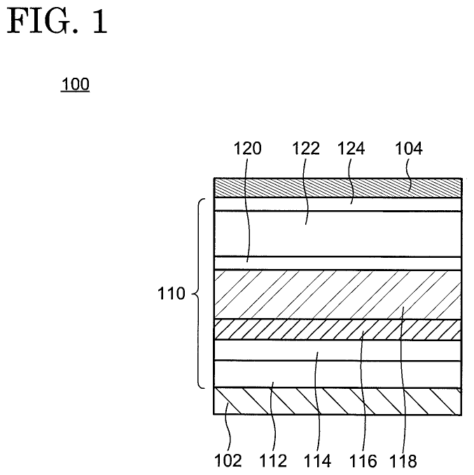

A schematic cross-sectional view of the light-emitting element 100 is shown in FIG. 1. As shown in FIG. 1, the light-emitting element 100 has an anode 102 and a cathode 104 facing each other and includes an electroluminescence layer (hereinafter also referred to as an EL layer) 110 between the anode 102 and the cathode 104. The EL layer 110 is composed of a plurality of functional layers including organic compounds. The EL layer 110 includes an emission layer 118 contributing to light emission as well as an electron-blocking layer 116 arranged between the emission layer 118 and the anode 102 and in contact with the emission layer 118. The EL layer 110 may further include a hole-injection layer 112, a hole-transporting layer 114, a hole-blocking layer 120, an electron-transporting layer 122, an electron-injection layer 124, and the like. When a potential difference is created between the anode 102 and cathode 104, holes and electrons are injected into the EL layer 110 from the anode 102 and cathode 104, respectively, and these carriers recombine in the emission layer 118. The emission material in the emission layer 118 is excited by the recombination of the holes and the electrons, and the energy released when this excited state returns to the ground state can be extracted as light. Hereinafter, each component is explained.

### 2. Anode and Cathode

The anode 102 is an electrode for injecting holes into the EL layer 110. Since the anode 102 is configured to transmit visible light in the case where the light obtained in the EL layer 110 is extracted through the anode 102, the anode 102 is structured with a conductive oxide transmitting visible light such as indium-tin oxide (ITO) and indium-zinc oxide (IZO). On the other hand, when the light is extracted through the cathode 104, the anode 102 is configured to function as a reflective electrode efficiently reflecting the light. In this case, the anode 102 is configured to include a metal with high reflectivity such as silver and aluminum or an alloy thereof. For example, a structure in which a film containing a metal is sandwiched between films containing a conductive oxide may be applied to the anode 102.

The cathode 104 is an electrode for injecting electrons into the EL layer 110. Since the cathode 104 also functions as a reflecting electrode in the case where the light obtained in the EL layer 110 is extracted through the anode 102, the cathode 104 is configured to include the aforementioned metal or alloy (e.g., an alloy of silver and a metal having a small work function such as magnesium). On the other hand, when the light obtained in the EL layer 110 is extracted through the cathode 104, the cathode 104 is configured to include a conductive oxide transmitting visible light. Alternatively, a metal-containing film having a thickness (e.g., equal to or greater than 5 nm and equal to or less than 20 nm) allowing visible light to pass therethrough may be used as the cathode 104. In the latter case, a film of a conductive oxide transmitting visible light may further be provided over the metal-containing film.

### 3. Hole-Injection Layer

The hole-injection layer 112 functions to promote hole injection from the anode 102 to the EL layer 110. A compound to which holes are easily injected, i.e., a (electron-donating) compound which is readily oxidized can be used in the hole-injection layer 112. In other words, a compound with a shallow highest occupied molecular orbital (HOMO) level can be used. For example, an aromatic amine such as a benzidine derivative and a triarylamine, a carbazole derivative, a thiophene derivative, a phthalocyanine derivative such as copper phthalocyanine, and the like can be used. Alternatively, a polymeric material such as polythiophene, polyaniline, and their derivatives can be used, and poly(ethylenedioxythiophene)/poly(styrenesulfonic acid) is represented as an example. A mixture of an electron-donating compound such as the aforementioned aromatic amine and carbazole derivative and an aromatic hydrocarbon with an electron acceptor may be used. The electron acceptor includes a transition metal oxide such as vanadium oxide and molybdenum oxide, a nitrogen-containing heteroaromatic compound, and an aromatic compound with a strong electron-withdrawing group such as a cyano group. The hole-injection layer 112 may have a single layer structure or may be composed of a plurality of layers containing different materials.

### 4. Hole-Transporting Layer

The hole-transporting layer 114 is provided in contact with the hole-injection layer 112. The hole-transporting layer 114 has a function of transporting the holes injected into the hole-injection layer 112 to the emission layer 118, and a material the same as or similar to the material usable in the hole-injection layer 112 can be used. For example, a material with a deeper HOMO level than the hole-injection layer 112, but with a difference therebetween of 0.5 eV or less can be used. Typically, an aromatic amine such as a benzidine derivative may be used. The hole-transporting layer 114 may also have a single layer structure or may be composed of a plurality of layers containing different materials.

### 5. Electron-Blocking Layer

The electron-blocking layer 116 is provided in contact with the hole-transporting layer 114. The electron-blocking layer 116 has a function to confine electrons in the emission layer 118 by preventing the electrons injected from the cathode 104 from passing through the emission layer 118 and being injected into the hole-transporting layer 114 without contributing to recombination in the emission layer 118 as well as a function to prevent energy transfer from the excitation energy obtained in the emission layer 120 to the molecules in the hole-transporting layer 114. These functions prevent a decrease in emission efficiency.

The electron-blocking layer 116 contains an electron-blocking material. Preferably, the electron-blocking layer 116 consists of an electron-blocking material. It is preferable to use a material as the electron-blocking material which has higher or comparable hole transport properties than electron transport properties and which has a shallower lowest unoccupied molecular orbital (LUMO) level and a larger band gap than the host material in the emission layer 118. It is possible to prevent the electrons from passing through the emission layer 118 and increase the efficiency of the light-emitting element 100 by setting the LUMO level of the electron-blocking material to be shallower than that of the host material.

The electron-blocking material is different in structure from the host material in the emission layer 118 described below. Moreover, the electron-blocking layer 116 is configured so that the resistance of the light-emitting element 100 is equal to or greater than 101.0% and equal to or less than 104.0%, equal to or greater than 101.2% and equal to or less than 103.7%, or equal to or greater than 101.2% and equal to or less than 102.5% with respect to the resistance of a reference element obtained by replacing the electron-blocking material of the light-emitting element 100 with the host material in the emission layer 118. The reference element is only different in the electron-blocking material from the light-emitting element 100, and all of other structures are the same. Here, a resistance of a light-emitting element is a resistance between an anode and a cathode when a current flows at a constant current density between the anode and the cathode. That is, the resistance R is defined as V/I where the current flowing between the anode and the cathode when a voltage V is applied therebetween is defined as I. The current density at this time is a current density in a saturated region. The saturated region is a region where the current efficiency does not increase with increasing current density in a current density —current efficiency plot of a light-emitting element, and is 10 mA/cm², for example. The light-emitting element 100 and the electron-blocking layer 116 are configured in this manner, by which the external quantum efficiency can be increased and reliability (element lifetime) can be improved without an increase in driving voltage as demonstrated in Examples.

A difference in the LUMO level between the electron-blocking material and the host material is preferred to be greater than 0 eV and equal to or less than 0.1 eV. As demonstrated in Examples, it is possible not only to effectively prevent the electrons from passing through the emission layer 118 but also to secure preferrable carrier balance by setting the difference in the LUMO level between the electron-blocking material and the host material to be small in such a way. Furthermore, the HOMO level of the electron-blocking material is preferred to be deeper than the HOMO level of the host material and a difference therebetween is preferred to be equal to or greater than 0.1 eV and equal to or less than 0.3 eV. Selection of the electron-blocking material and the host material in such a manner enables efficient transportation of the holes, while preventing the energy transfer from the emission layer 118.

Specific electron-blocking materials include an aromatic amine derivative, a carbazole derivative, a 9,10-dihydroacridine derivative, a benzofuran derivative, and a benzothiophene derivative.

### 6. Emission Layer

The emission layer 118 is provided over and in contact with the electron-blocking layer 116. The emission layer 118 contains, as its main component, a host material different in structure from the electron-blocking material as well as an emission material responsible for light emission. The volume ratio of the host material to the emission material (emission material/host material) may be, for example, equal to or greater than 0.30 and equal to or less than 0.6. A variety of compounds may be used as the host material, depending on the emission wavelength of the emission material. For example, as the host material, an oxadiazole derivative, a triazole derivative, a benzimidazole derivative, a quinoxaline derivative, a dibenzoquinoxaline derivative, a dibenzothiophene derivative, a dibenzofuran derivative, a pyrimidine derivative, a triazine derivative, a pyridine derivative, a bipyridine derivative, a phenanthroline derivative, an aromatic amine derivative, and a carbazole derivative can be used in addition to zinc and aluminum-based metal complexes.

A material exhibiting thermally activated delayed fluorescence (TADF) (thermally activated delayed fluorescent material) is used as the emission material. In a thermally activated delayed fluorescent material, the difference between the triplet and singlet excitation energy levels is small and is, for example, equal to or greater than 5 meV and equal to or less than 20 meV. Therefore, the triplet excited state of the emission material produced by carrier recombination is able to undergo intersystem crossing to the singlet excited state with extremely small thermal energy such as that of room temperature or lower. As a result, the rate of thermal deactivation of the triplet excited state is relatively reduced, and radiative deactivation from the singlet excited state is promoted. This mechanism dramatically improves the efficiency of the light-emitting element 100. Due to the emission governed by this mechanism, the thermally activated delayed fluorescent material exhibits emission with a remarkably long lifetime while providing a spectrum similar to that of normal fluorescence. The fluorescence lifetime of the thermally activated delayed fluorescent material is 10⁻⁶ seconds (1 ns) or longer, preferably 10⁻³ seconds (1 μs) or longer.

There is no restriction on the emission color of the thermally activated delayed fluorescence material, and blue-, green-, and red-emissive thermally activated delayed fluorescence materials can be used on the basis of the emission color required by the light-emitting element 100. Preferably, the thermally activated delayed fluorescence material emits green or red light, and more preferably, emits green light. Here, blue emission refers to emission with a maximum emission peak wavelength in the range equal to or longer than 400 nm and equal to or shorter than 500 nm, green emission refers to emission with a maximum emission peak wavelength in the range equal to or longer than 500 nm and equal to or shorter than 650 nm, and red emission refers to emission with a maximum emission peak wavelength in the range equal to or longer than 650 nm and equal to or shorter than 750 nm.

Examples of the thermally activated delayed fluorescence materials include a fullerene and its derivatives, an acridine derivative such as proflavine, eosin, and the like. A metal-containing porphyrin containing magnesium, zinc, cadmium, tin, platinum, indium, or palladium is also represented. A metal-containing porphyrin includes, for example, a protoporphyrin-tin fluoride complex, a mesoporphyrin-tin fluoride complex, a hematoporphyrin-tin fluoride complex, a coproporphyrin tetramethyl ester-tin fluoride complex, an octaethylporphyrin-tin fluoride complex, an ethioporphyrin-tin fluoride complex, an octaethylporphyrin-platinum chloride complex, and the like.

In addition, a compound in which an electron-donor component and an electron-acceptor component are linked may be used. As the electron-donor component and the electron-acceptor component, a TT-electron-excessive heteroaromatic ring and a TT-electron-deficient heteroaromatic ring are respectively represented. The basic skeleton of the TT-electron-excessive heteroaromatic ring includes a pyridine skeleton, a diazine skeleton, a triazine skeleton, and the like. The basic skeleton of the TT-electron-deficient heteroaromatic ring includes an acridine skeleton, a phenoxazine skeleton, a phenothiazine skeleton, a furan skeleton, a thiophene skeleton, a pyrrole skeleton, and the like. As such compounds, 2-(biphenyl-4-yl)-4,6-bis(12-phenylindolo [2,3-a]carbazole-11-yl)-1,3,5-triazine, 9-(4,6-diphenyl-1,3,5-triazine-2-yl)-9′-phenyl-9H,9′H-3,3′-bicarbazole, 9-[4-(4,6-diphenyl-1,3,5-triazine-2-yl)phenyl]-9′-phenyl-9H,9′H-3,3-biucarbazole, 2-[4-(10H-phenoxazin-10-yl)phenyl]-4,6-diphenyl-1,3,5-triazine, and the like are exemplified.

The emission layer 118 may further include, as the emission material, a fluorescent material (hereinafter also referred to as a second emission material) capable of receiving the singlet excited energy of the thermally activated delayed fluorescence material and forming a singlet excited state in addition to the thermally activated delayed fluorescence material. The second emission material is selected so that the energy level of its singlet excited state is lower than that of the thermally activated delayed fluorescent material, i.e., its band gap is smaller than that of the thermally activated delayed fluorescent material. The second emission material does not exhibit thermally activated delayed fluorescence in the light-emitting element 100 and thus exhibits a relatively short fluorescence lifetime (e.g., equal to or longer than 1 ps and equal to or shorter than 1 ns). Specifically, a fluorescent material such as a coumarin derivative, a pyran derivative, a quinacridone derivative, a tetracene derivative, a pyrene derivative, an anthracene derivative, and a pyran derivative are exemplified. In general, the emission spectrum exhibited by thermally activated delayed fluorescent materials is broad and has low color purity. In contrast, since the fluorescent materials described above provide an emission spectrum with a relatively narrow half width, they are capable of emitting light with high color purity. Therefore, further addition of the second emission material to the emission layer 118 enables the production of the light-emitting element 100 with excellent color purity in addition to high emission efficiency resulting from the thermally activated delayed fluorescence material.

### 7. Hole-Blocking Layer

The hole-blocking layer 120 has a function to confine the holes injected from the anode 102 within the emission layer 118 by preventing the holes from passing through the emission layer 118 and being injected into the electron-transporting layer 122 without contributing to recombination as well as a function to prevent the excitation energy obtained in the emission layer 118 from being transferred to the molecules in the electron-transporting layer 122. This mechanism prevents a decrease in emission efficiency.

For the hole-blocking layer 120, it is preferable to use a material having higher or comparable electron-transporting properties than hole-transporting properties as well as a deeper HOMO level and larger band gap than the molecules in the emission layer 118. Specifically, the difference between the HOMO level of the molecules in the hole-blocking layer 120 and that of the molecules in the emission layer 118 is preferred to be 0.2 eV or greater, 0.3 eV or greater, or 0.5 eV or greater. The difference between the band gap of the molecules in the hole-blocking layer 120 and that of the molecules in the emission layer 118 is also preferred to be 0.2 eV or greater, 0.3 eV or greater, or 0.5 eV or greater. Specifically, a phenanthroline derivative, an oxadiazole derivative, a triazole derivative, a metal complex having a relatively large band gap (e.g., 2.8 eV or higher) such as bis(2-methyl-8-quinolinolato) (4-hydroxy-biphenylyl) aluminum, and the like are represented. The hole-blocking layer 120 may also have a single layer structure or may be composed of a plurality of layers containing different materials.

### 8. Electron-Transporting Layer

The electron-transporting layer 122 functions to transport the electrons injected from the cathode 104 via the electron-injection layer 124 to the emission layer 118. A readily reduced (electron-accepting) compound can be used for the electron-transporting layer 122. In other words, a compound with a shallow LUMO level may be used. For example, a metal complex containing a ligand having benzoquinolinol as the basic skeleton such as tris(8-quinolinolato) aluminum and tris(4-methyl-8-quinolinolato) aluminum, a metal complex containing a ligand having oxadiazole or thiazole as the basic skeleton, and the like are represented. In addition to these metal complexes, a compound with an electron-deficient heteroaromatic ring such as an oxadiazole derivative, a thiazole derivative, a triazole derivative, and a phenanthroline derivative may be used. The electron-transporting layer 122 may also have a single layer structure or may be composed of a plurality of layers containing different materials.

### 9. Electron-Injection Layer

For the electron-injection layer 124, a compound promoting electron injection from the cathode 104 to the electron-transporting layer 122 can be used. For example, a mixture of a compound which can be used for the electron-transporting layer 122 and an electron donor such as lithium and magnesium may be used. Alternatively, an inorganic compound such as lithium fluoride and calcium fluoride may be used.

It is relatively difficult to achieve appropriate carrier balance in light-emitting elements including an emission material exhibiting thermally activated delayed fluorescence, and the carrier balance is readily affected by the electron-blocking layer. Hence, when the electron-blocking material is not appropriately selected, carriers (electrons) readily pass through the emission layer to cause the recombination region to shift to the anode side, resulting in an increase in the proportion of non-radiative recombination and a decrease in emission efficiency. This phenomenon significantly affects the reliability of light-emitting elements.

It is necessary to provide an electron-injection barrier between the electron-blocking layer and the emission layer in order to prevent the carriers from passing through the emission layer. That is, light emitting elements are designed so that the LUMO level of the electron-blocking layer is higher than that of the emission layer. However, when the difference in LUMO level is too large (e.g., 0.2 eV), carrier accumulation occurs between the electron-blocking layer and the emission layer immediately after driving light-emitting elements as demonstrated in the Examples. Accordingly, a large internal electric field is generated in light-emitting elements to inhibit carrier injection. This phenomenon not only results in an increase in a driving voltage but also promotes the non-radiative recombination of the accumulated carriers, leading to a decrease in emission efficiency and reliability.

On the other hand, in the light-emitting element 100, the electron-blocking layer is configured so that the resistance of the light-emitting element 100 is equal to or greater than 101.2% and equal to or less than 103.7% or equal to or greater than 101.2% and equal to or less than 102.5% with respect to the reference element. The light-emitting element 100 may also be configured so that the difference in LUMO level between the electron-blocking layer 116 and the emission layer 118 is equal to or less than 0.1 eV. Formation of an extremely small energy barrier with respect to the electron injection from the emission layer 118 to the electron-blocking layer 116 effectively suppresses the carrier accumulation and the generation of an internal electric field caused by the carrier accumulation compared with a light-emitting element without the energy barrier. Therefore, the light-emitting element 100 can be driven at a lower driving voltage. Furthermore, since the non-radiative recombination caused by the carrier accumulation is suppressed, the light-emitting element 100 exhibits higher emission efficiency and reliability. Hence, implementation of the embodiment of the present invention enables the production of highly efficient and reliable light-emitting elements.

### Second Embodiment

In the present embodiment, a display device 200 including the light-emitting element 100 described in the First Embodiment is explained. An explanation of the structure the same as or similar to that described in the First Embodiment may be omitted.

### 1. Overall Structure

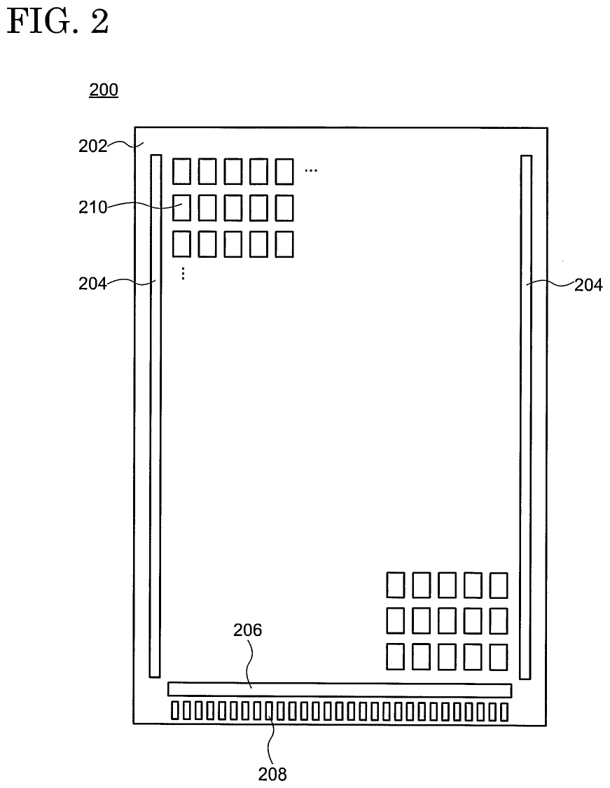

A schematic top view of the display device 200 is shown in FIG. 2. As shown in FIG. 2, the display device 200 has a substrate 202 over which a variety of patterned insulating films, semiconductor films, and conductor films is stacked. Appropriate stacking of these films leads to the formation of a plurality of pixels 210, driver circuits for driving the pixels 210 (scanning-line driver circuits 204 and a signal-line driver circuit 206), and the like over the substrate 202. A counter substrate which is not illustrated in FIG. 2 is provided over the pixels 210, the scanning-line driver circuits 204, and the signal-line driver circuit 206. The substrate 202 and the counter substrate are secured by an adhesive such as a sealant, by which the pixels 210, the scanning-line driver circuits 204, and the signal-line driver circuit 206 are sealed and protected. A plurality of terminals 208 formed with a conductive film is provided over the substrate 202, and the terminals 208 are electrically connected to an external circuit which is not illustrated via a connector such as a flexible printed circuit (FPC) board. A variety of signals and power for displaying images are supplied from the external circuit to the scanning-line driver circuits 204 and the signal-line driver circuit 206 through the terminals 208. Note that either or both of the scanning-line driver circuits 204 and the signal-line driver circuit 206 need not be formed directly over the substrate 202, and a driver circuit formed over a substrate different from the substrate 202 (such as a semiconductor substrate) may be mounted over the substrate 202 or the connector.

In each of the pixels 210, a pixel circuit is formed, and one of the light-emitting elements giving the three primary colors (i.e., a red-emissive light-emitting element, a green-emissive light-emitting element, and a blue-emissive light-emitting element) is further arranged. Signals to drive the pixel circuits are generated by the scanning-line driver circuits 204 and the signal-line driver circuit 206 on the basis of various signals supplied from the external circuits, by which the light-emitting elements connected to the pixel circuits emit light to allow each of the 210 pixels to function as the smallest unit providing color information. As a result, full-color display can be performed. Here, a red-emissive light-emitting element, a green-emissive light-emitting element, and a blue-emissive light-emitting element are, for example, elements respectively exhibiting emission peak wavelengths in the range equal to or longer than 650 nm and equal to or shorter than 750 nm, equal to or longer than 500 nm and equal to or shorter than 650 nm, and equal to or longer than 400 nm and equal to or shorter than 500 nm.

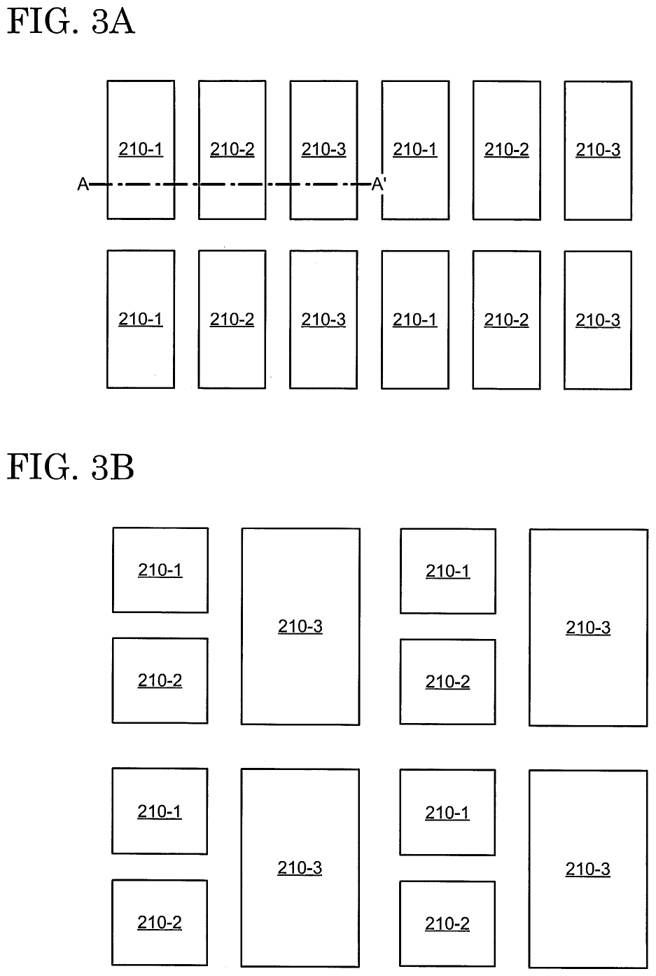

There is no restriction on the arrangement of the pixels 210. For example, the stripe arrangement may be employed in which the red-, green-, and blue-emissive pixels 210-1, 210-2, and 210-3 respectively providing red, green, and blue light are arranged sequentially in the line direction, and the pixels 210 providing the same emission color are arranged in the same row as shown in FIG. 3A. Alternatively, although not illustrated, in addition to the mosaic arrangement in which the red-emissive pixel 210-1, the green-emissive pixel 210-2, and the blue-emissive pixel 210-3 are sequentially arranged in both the row and column directions, a variety of arrangements such as the delta arrangement and the pentile arrangement may be employed. Alternatively, the plurality of pixels 210 may be arranged so that one or more red-emissive pixels 210-1 and one or more green-emissive pixels 210-2 are sandwiched between adjacent blue-emissive pixels 210-3 as shown in FIG. 3B. In this arrangement, the plurality of pixels 210 may be arranged so that the blue-emissive pixel 210-3 in which the blue-emissive light-emitting element with the lowest emission efficiency is arranged has a larger area than the other pixels 210, by which the burden on the blue-emissive light-emitting element is reduced and the reliability of the display device 200 can be improved.

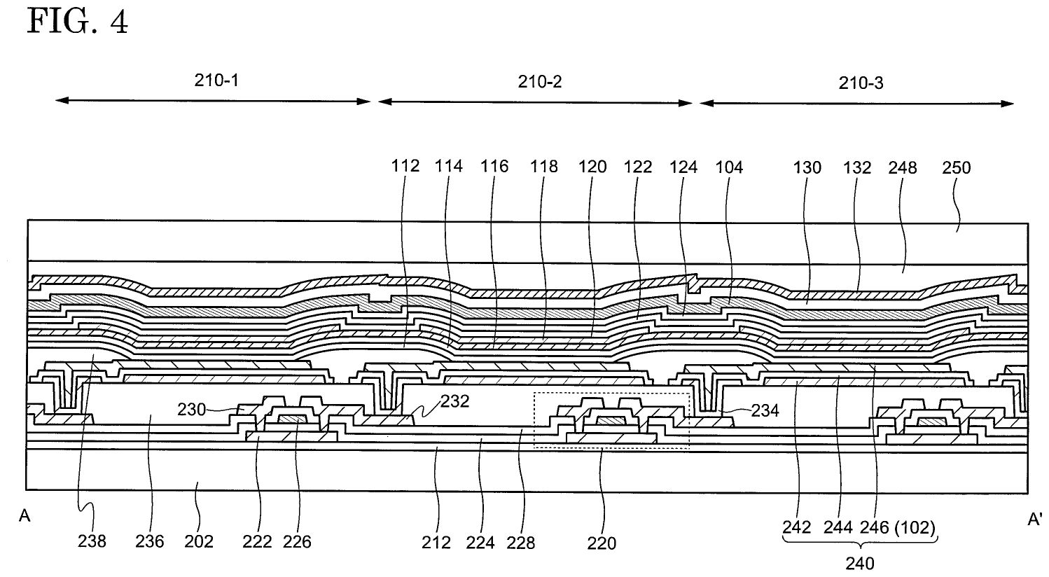

A schematic view of a cross section along the chain line A-A′ in FIG. 3A is shown in FIG. 4. In FIG. 4, the cross section including the continuously arranged red-emissive pixel 210-1, green-emissive pixel 210-2, and blue-emissive pixel 210-3 are schematically illustrated. The configuration of the pixel circuit formed in each of the pixels 210 may be arbitrarily determined, and any known configuration may be applied. In the example shown in FIG. 4, one transistor 220 and a capacitor element (auxiliary capacitor element) 240 connected to the transistor 220 are shown as part of the elements structuring the pixel circuit. Furthermore, a light-emitting element connected to the pixel circuit is provided in each pixel 210. Although an example is demonstrated here in which the light from the emission layers 118 is extracted through the counter substrate 250 in all of the light-emitting elements, the display device 200 may be configured so that the light from the emission layers 118 is extracted through the substrate 202.

### 2. Substrate and Counter Substrate

The substrate 202 and the counter substrate 250 are provided to give physical strength to the display device 200 and to protect the plurality of pixels 210, the scanning-line driver circuits 204, and the signal-line driver circuit 206. The substrate 202 and the counter substrate 250 may be an inorganic material-containing substrate such as a crystalline semiconductor substrate, a glass substrate, and a quartz substrate or may contain a polymer such as a polyimide, a polyamide, and a polycarbonate. The substrate 202 and the counter substrate 250 may or may not be flexible. In the former case, the substrate 202 and/or the counter substrate 250 may be sufficiently flexible to be elastically deformed or highly flexible enough to be plastically deformed. When the emission from the light-emitting elements is extracted through the counter substrate 250, at least the counter substrate 250 is configured to transmit visible light. Conversely, when the emission from the light-emitting elements is extracted through the substrate 202, at least the substrate 202 is configured to transmit visible light.

### 3. Pixel Circuit

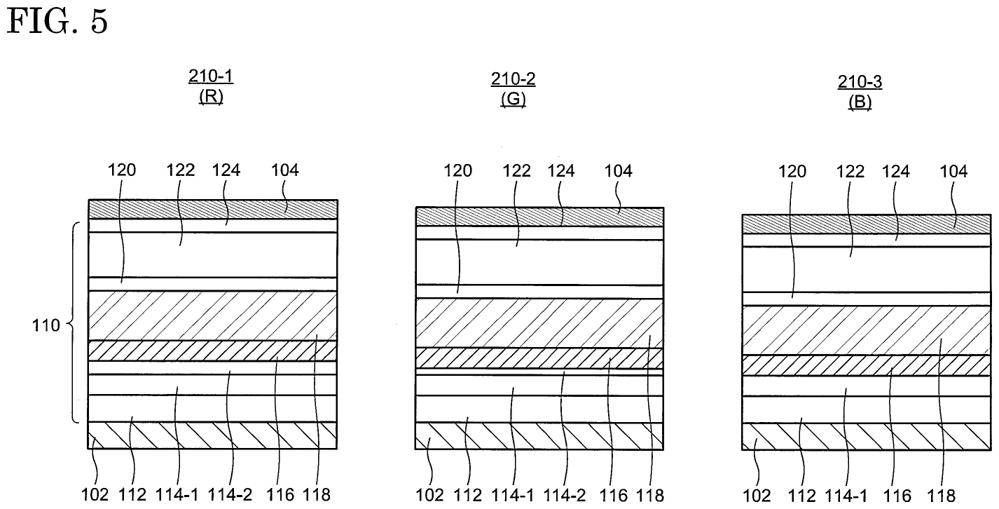

As described above, since a known configuration may be applied as the pixel circuit, a detailed description is omitted. In the example shown in FIG. 5, the transistor 220 functioning as a driving transistor is provided over the substrate 202. The transistor 220 may be provided directly over the substrate 202 or may be formed over the substrate 202 through an undercoat 212 which prevents the diffusion of impurities contained in the substrate 202. The transistor 220 shown in FIG. 5 is composed of a semiconductor film 222, a gate insulating film 224 over the semiconductor film 222, a gate electrode 226 over the gate insulating film 224, an interlayer insulating film 228 over the gate electrode 226, and a pair of terminals 230 and 232 disposed over the interlayer insulating film 228 and electrically connected to the semiconductor film 222. Although the transistor 220 shown here is a top-gate type transistor, there is no restriction on the structure of the transistor 220, and a bottom-gate type transistor or a transistor having gate electrodes over and under the semiconductor film may be used as the transistor 220.

A leveling film 236 is provided over the transistor 220 to absorb unevenness caused by the elements such as the transistor 220 included in the pixel circuit and to provide a flat surface. The capacitor electrode 242, a capacitor insulating film 244 over the capacitor electrode 242, and a pixel electrode 246 may be arranged over the leveling film 236, and the capacitor element 240 can be fabricated by these components. Here, the pixel electrode 246 functions as the anode 102 of the light-emitting element 100. An opening is provided in the leveling film 236 to expose the terminal 232, and the pixel electrode 246 is electrically connected to the terminal 232 at this opening either directly or via a connecting electrode 234 covering this opening. A partition wall 238, which is an insulating film, is provided to cover the edge of the pixel electrode 246, and the EL layer 110 is arranged to cover the pixel electrode 246 and the partition wall 238. This structure electrically insulates adjacent light-emitting elements 100 and prevents the EL layer 110 from being disconnected by the edge of the pixel electrode 246. Note that, in the example shown in FIG. 4, the pixel electrode 246 is shared by the light-emitting element 100 and the capacitor element 240.

### 4. Light-Emitting Element

The light-emitting element 100 is arranged in at least one of the red-emissive pixel 210-1, the green-emissive pixel 210-2, and the blue-emissive pixel 210-3. The light-emitting element 100 may be arranged in all of the red-emissive pixel 210-1, the green-emissive pixel 210-2, and the blue-emissive pixel 210-3 or may be arranged in a part of the pixels 210. For example, the light-emitting element 100 may be arranged in the red-emissive pixel 210-1 and the green-emissive pixel 210-2, while a light-emitting element different in structure from the light-emitting element 100 may be arranged in the blue-emissive pixel 210-3. Alternatively, the light-emitting element 100 may be arranged in one of the red-emissive pixel 210-1 and the green-emissive pixel 210-2, while a light-emitting element different in structure from the light-emitting element 100 may be arranged in the other pixel and the blue-emissive pixel 210-3. Here, a light-emitting element different in structure from the light-emitting element 100 is represented by a light-emitting element including a phosphorescence material or a fluorescence material (which does not exhibit thermally activated delayed fluorescence). Alternatively, a light-emitting element which includes a thermally activated delayed fluorescence material but does not have the electron-blocking layer or a light-emitting element in which the electron-blocking material is the same as the host material may be used as a light-emitting element different in structure from the light-emitting element 100. Alternatively, a light-emitting element may be employed in which the electron-blocking material and the host material are different from each other but a resistance thereof with respect to the reference element obtained by replacing the electron-blocking layer with the host material deviates from the aforementioned range. Alternatively, a light-emitting element may be employed in which the electron-blocking material and the host material are different from each other but the relationship of the HOMO levels or the LUMO levels therebetween deviates from the aforementioned range.

The emission layer 118 is separated between the red-emissive pixel 210-1, the green-emissive pixel 210-2, and the blue-emissive pixel 210-3 because the structure of the emission layer 118 determines the emission color. On the other hand, a part or all of the functional layers other than the emission layer 118 may be provided to be continuous over the adjacent pixels 210 so as to be shared by the adjacent pixels 210 or may be provided so as to be divided between the adjacent pixels 210. For example, the electron-blocking layer 116 may be formed so as to be shared by and continuous over all of the pixels 210 as shown in FIG. 4. Alternatively, the hole-injection layer 112, the hole-transporting layer 114, the hole-blocking layer 120, the electron-transporting layer 122, the electron-injected layer 124, and the cathode 104 as well as the electron-blocking layer 116 may be formed so as to be shared by and continuous over all of the pixels 210.

### 5. Other Components

As an optional component, one or a plurality of cap layers 130 may be provided over the cathode 104 to resonate the light extracted from the cathode 104 to improve color purity and luminance in the frontal direction. In addition, a protective film 132 may be disposed over the light-emitting elements to prevent impurities such as water and oxygen from entering the EL layer 110. The protective film 132 may be composed of, for example, a film containing silicon nitride, a film containing a polymer such as an acrylic resin and an epoxy resin, or a stack thereof.

### 6. Modified Examples

Although the configuration of the hole-transporting layer 114 (number of stacked layers and/or thickness) is the same in all of the pixels 210 in the example shown in FIG. 4, the configuration of the hole-transporting layer 114 may differ between the pixels 210. For example, the number of stacked layers and/or thickness of the hole-transporting layer 114 may differ between the red-emissive pixel 210-1, the green-emissive pixel 210-2, and the blue-emissive pixel 210-3 as shown in FIG. 5. Preferably, the pixels 210 are configured so as to have a larger number of stacked layers and/or thickness of the hole-transporting layer 114 in the pixel 210 providing a longer wavelength. This structure allows the formation of a more effective resonator structure using the EL layer 110. For example, a first hole-transporting layer 114-1 may be continuously formed over all of the pixels 210, and a second hole-transporting layer 114-2 may be further formed over the first hole-transporting layer 114-2 in the red-emissive pixel 210-1 and the green-emissive pixel 210-2. At this time, the pixels 210 may be configured so that the thickness of the second hole-transporting layer 114-2 of the red-emissive pixel 210-1 is larger than that of the green-emissive pixel 210-2. Although not illustrated, the number of stacked layers of the hole-transporting layer 114 may be varied for each pixel 210.

As described in the First Embodiment, the light-emitting element 100 exhibits extremely high efficiency because it contains a thermally activated delayed fluorescence material. Moreover, it is possible to reduce the driving voltage and increase the emission efficiency and reliability by configuring the electron-blocking layer 116 so that a resistance change at the time when the electron-blocking material is replaced with the host material in the light-emitting element 100 and the relationship between the LUMO levels of the electron-blocking material and the host material meet the relationship described in the First Embodiment. Therefore, implementation of the embodiment of the present invention allows the production of display devices having high efficiency and reliability.

### EXAMPLES

Light-emitting elements of Example and Comparable Examples 1 and 2 were fabricated, and the characteristics thereof were evaluated. In all of the light-emitting elements, ITO was used as the anode, and a co-evaporation film of silver and magnesium was used as the cathode. The size of the emission region was 2.0 mm×2.0 mm. In each light-emitting element, the emission layer includes a green-emissive thermally activated delayed fluorescence material, and the materials structuring the functional layers were the same between all of the light-emitting elements other than the electron-blocking layer. The thicknesses of the functional layers structuring the EL layer are as shown in Table 1. Here, the electron-blocking material is the same as the host material of the emission layer in the light-emitting element of the Comparable Example 2. Therefore, the LUMO levels are the same between the electron-blocking layer and the emission layer. On the other hand, the LUMO level of the electron-blocking layer was shallower than that of the emission layer and the difference therebetween was 0.2 eV and 0.1 eV, respectively, in the light-emitting elements of the Comparable Example 1 and the Example.

TABLE 1
Thicknesses of EL layers of light-emitting elements of Example and Comparable Examples (nm)

| | Hole- | Hole- | Electron- | | | Hole- | Electron- | Electron- |
|---|---|---|---|---|---|---|---|---|
| | injection | transporting | blocking | Emission | ΔLUMO | blocking | transporting | injection |
| Elements | layer | layer | layer | layer | (eV)^{a} | layer | layer | layer |
| Comparable | 17 | 40 | 5 | 45 | 0.2 | 10 | 20 | 2 |
| Example 1 | | | | | | | | |
| Comparable | 17 | 40 | 5 | 45 | 0 | 10 | 20 | 2 |
| Example 2 | | | | | | | | |
| Example | 17 | 40 | 5 | 45 | 0.1 | 10 | 20 | 2 |

^{a}Difference in LUMO level between electron-blocking layer and emission layer.

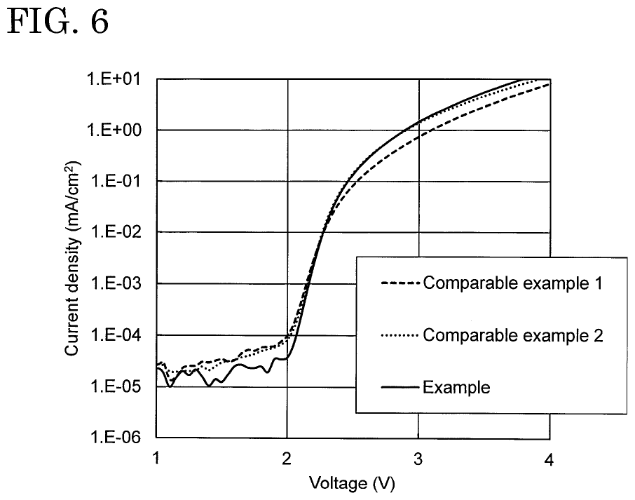

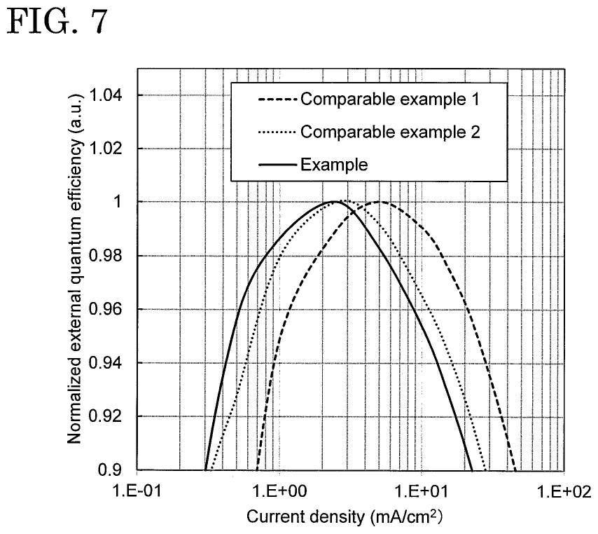

Voltage-current density plots of the fabricated light-emitting elements are shown in FIG. 6. It was found from FIG. 6 that the voltage-current density characteristics of the light-emitting element of the Example shift to a low-voltage side compared with the Comparable Example 2 although there is an electron-injection barrier between the electron-blocking layer and the emission layer. In particular, it was found that the light-emitting element of the Example can be driven at a lower voltage than the Comparable Examples 1 and 2 in the high current-density region. Moreover, as can be seen from the current density-normalized external quantum efficiency curves (FIG. 7), the efficiency of the Comparable Example 2 having no electron-injection barrier between the electron-blocking layer and the emission layer is low at a low current-density region. Furthermore, the normalized external quantum efficiency at a low current-density region is not consistent with the order of the magnitude of the electron-injection barrier between the electron-blocking layer and the emission layer, and the light-emitting element of the Example (ΔLUMO=0.1 eV) exhibits the highest efficiency.

Various properties of these light-emitting elements are summarized in Table 2. The light-emitting element of the Example exhibits the lowest driving voltage and also has higher current efficiency and reliability.

TABLE 2
Various properties of light-emitting elements of Example and
Comparable Examples

| | Voltage^{a} | Current efficiency^{b} | Reliability^{c} |
|---|---|---|---|
| | (V) | (cd/A) | (h) |
| Comparable | 4.10 | 65.4 | 23 |
| Example 1 | | | |
| Comparable | 3.90 | 73.7 | 39 |
| Example 2 | | | |
| Example | 3.86 | 81.6 | 44 |

^{a}Driving voltage at current efficiency of 1 mA/cm²
^{b}Current efficiency at current density of 1 mA/cm²
^{c}Time of 5% reduction of luminance from initial luminance when driving at current density of 1 mA/cm²

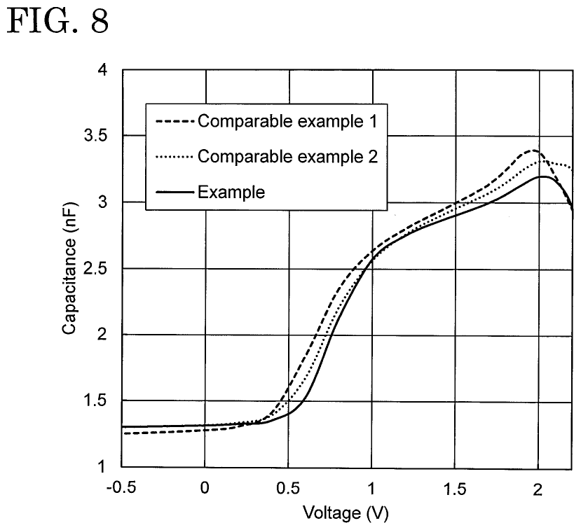

It is considered that these results can be explained on the basis of generation behavior of the internal electric field in the EL layer. In the voltage-capacitance plots obtained by impedance spectroscopy (FIG. 8), a large capacitance was observed from a low-voltage region in the light-emitting element of the Example 1, suggesting that carriers are accumulated in the EL layer to generate an internal electric field at an early stage of driving the light-emitting element. In contrast, it can be found from the results of FIG. 8 that the capacitance generation is suppressed in a low-voltage region in the Comparable Example 2 having no electron-injection barrier between the electron-blocking layer and the emission layer compared with the Comparable Example 1. It should be noted that the generation of the internal electric field can be more efficiently suppressed in the light-emitting element of the Example provided with a small electron-injection barrier (ΔLUMO=0.1 eV). From these results, it is considered that the carrier accumulation can be suppressed by regulating the electron-injection barrier between the electron-blocking layer and the emission layer, i.e., the difference in LUMO level between these layers, to be 0.1 eV or less, by which the non-radiative recombination is suppressed to increase the normalized external quantum efficiency, reduce the driving voltage, and improve the reliability.

The above results demonstrate that implementation of the embodiment of the present invention allows the production of light-emitting elements having extremely low power consumption and improved reliability as well as display devices including these light-emitting elements.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of the light-emitting elements and display devices according to each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A light-emitting element comprising an anode, a cathode, and an electroluminescence layer between the anode and the cathode, the electroluminescence layer comprising:
an electron-blocking layer containing an electron-blocking material; and
an emission layer over and in contact with the electron-blocking layer and containing a host material and a first emission material exhibiting thermally activated delayed fluorescence,
wherein the light-emitting element is configured so that a resistance is equal to or greater than 101.0% and equal to or less than 104.0% of a resistance in a case where the electron-blocking material is replaced with the host material, and
the resistance is a resistance between the anode and the cathode when a current flows at a constant current density between the anode and the cathode.

2. The light-emitting element according to claim 1,
wherein the current density is 10 mA/cm².

3. The light-emitting element according to claim 1,
wherein a difference in a lowest unoccupied molecular orbital level between the electron-blocking material and the host material is equal to or less than 0.1 eV.

4. The light-emitting element according to claim 1,
wherein a difference in a highest occupied molecular orbital level between the electron-blocking material and the host material is equal to or less than 0.1 eV and equal to or less than 0.3 eV.

5. The light-emitting element according to claim 1,
wherein an energy difference between a triplet excited state and a singlet excited state of the first emission material is equal to or greater than 5 meV and equal to or less than 20 meV.

6. The light-emitting element according to claim 1,
wherein the emission layer further contains a second emission material, and
an energy level of a singlet excited state of the second emission material is lower than an energy level of a singlet excited state of the first emission material.

7. The light-emitting element according to claim 1,
wherein the electron-blocking layer consists of the electron-blocking material.

8. The light-emitting element according to claim 1,
wherein the first emission material is red emissive or green emissive.

9. A display device comprising a red-emissive pixel, a green-emissive pixel, and a blue-emissive pixel each comprising an electroluminescence element,
wherein the electroluminescence element of at least one of the red-emissive pixel, the green-emissive pixel, and the blue-emissive pixel comprises:
a pixel electrode;
an electron-blocking layer located over the pixel electrode and containing an electron-blocking material;
an emission layer over and in contact with the electron-blocking layer and containing a host material and a first emission material exhibiting thermally activated delayed fluorescence; and
a cathode over the emission layer,
wherein the electroluminescence element of the at least one of the red-emissive pixel, the green-emissive pixel, and the blue-emissive pixel is configured so that a resistance is equal to or greater than 101.0% and equal to or less than 104.0% of a resistance in a case where the electron-blocking material is replaced with the host material, and
the resistance is a resistance between the pixel electrode and the cathode when a current flows at a constant current density between the pixel electrode and the cathode.

10. The display device according to claim 9,
wherein the current density is 10 mA/cm².

11. The display device according to claim 9,
wherein a difference in a lowest unoccupied molecular orbital level between the electron-blocking material and the host material is equal to or less than 0.1 eV.

12. The display device according to claim 9,
wherein a difference in a highest occupied molecular orbital level between the electron-blocking material and the host material is equal to or less than 0.1 eV and equal to or less than 0.3 eV.

13. The display device according to claim 9,
wherein an energy difference between a triplet excited state and a singlet excited state of the first emission material is equal to or greater than 5 meV and equal to or less than 20 meV.

14. The display device according to claim 9,
wherein the emission layer further contains a second emission material, and
an energy level of a singlet excited state of the second emission material is lower than an energy level of a singlet excited state of the first emission material.

15. The display device according to claim 9,
wherein the electron-blocking layer consists of the electron-blocking material.

16. The display device according to claim 9,
wherein the first emission material is red emissive or green emissive.
